(19) United States
(12) Patent Application Publication
(10) Pub. No.: US 2010/0127280 A1
(43) Pub. Date: May 27, 2010

(54) PHOTO SENSOR AND DISPLAY DEVICE

(76) Inventors: Hiromi Katoh, Osaka (JP); Masakazu Satoh, Osaka (JP); Benjamin Hadwen, Oxford (GB)

Correspondence Address: NIXON & VANDERHYE, PC, 901 NORTH GLEBE ROAD, 11TH FLOOR, ARLINGTON, VA, 22203, US

(21) Appl. No.: 12/595,737

(22) PCT Filed: Apr. 10, 2008
(86) PCT No.: PCT/JP2008/057068

§ 371 Date: Oct. 13, 2009

(30) Foreign Application Priority Data
Apr. 13, 2007 (JP) 2007-106269

(51) Int. Cl. H01L 33/00; H01L 31/10; H01L 27/146

(52) U.S. Cl. 257/82; 257/292; 257/458; 257/E27.133; 257/E33.077; 257/E31.053; 257/443

(57) ABSTRACT

Provided is a photo sensor that can be downsized while suppressing occurrence of noise caused by a dark current, and a display device including the photo sensor. The photo sensor used includes a plurality of photodiodes (9-11) formed in a same silicon layer (8). The photodiodes (9-11) have p-type semiconductor regions (9a, 10a, 11a) and n-type semiconductor regions (9c, 10c, 11c) formed respectively in the silicon layer (8). Further, the photodiodes (9-11) are arranged in series so that the respective forward directions will be aligned with each other. In two photodiodes adjacent to each other, the n-type semiconductor region of one of the photodiodes and the p-type semiconductor region of the other photodiode are formed to overlap each other in the thickness direction of the silicon layer.

### TECHNICAL FIELD

The present invention relates to a photo sensor formed of a photodiode, and a display device including the photo sensor.

### BACKGROUND ART

In the field of display devices typified by liquid crystal display devices, a brightness of a display screen of a display device is adjusted according to an intensity of ambient light of the display device (hereinafter this light is referred to as “external light”). Therefore, to assemble a photo sensor in the display device has been proposed. The incorporation of the photo sensor in the display device can be achieved by mounting a photo sensor as a discrete component on a display panel thereof. Further, in the case of a liquid crystal display device, a photo sensor can be formed monolithically on an active matrix substrate by utilizing a process for forming an active element (TFT) and a peripheral circuit.

In the field of display devices for mobile terminal devices in particular, the photo sensor is required to be formed monolithically on the active matrix substrate, from the viewpoint of reducing the number of components and downsizing a display device. As the photo sensor formed monolithically, a photodiode having a lateral structure, for example, is known (see, for example, JP 2006-3857 A).

Each photodiode as disclosed in JP 2006-3857 A has a thin silicon layer formed on a glass substrate. A p-type semiconductor region (player), an intrinsic semiconductor region (i-layer) and an n-type semiconductor region (n-layer) are formed in this silicon layer in the planar direction, and the photodiode is composed of these player, i-layer and n-layer.

In a case of using such photodiode formed monolithically, a dark current will occur more easily in comparison with a case of using a photo sensor as a discrete component. The dark current is decreased rapidly when a voltage (reverse bias voltage) applied to the photodiode in a reverse direction comes proximate to zero, and is increased rapidly when the direction of the voltage applied to the photodiode is switched from the reverse direction to the forward direction. As a result, a ratio of a photoelectric current to the dark current, in other words, a ratio of signal to noise (S/N ratio) is raised rapidly when the reverse bias voltage applied to the photodiode comes proximate to 0 (zero) V.

Therefore, in a case of using the monolithically formed photodiode, a voltage control to keep the reverse bias voltage around 0 (zero) V is required for decreasing influences imposed by the dark current. However, since the range of the reverse bias voltage that can raise the S/N ratio is narrow due to the characteristics of the photodiode, the voltage control should be performed to suppress the voltage fluctuation within a small range, and that is very difficult.

From such points of view, a voltage control method of connecting a plurality of photodiodes in series and controlling a voltage applied to the both ends of this serial circuit has been proposed. In this case, the voltage applied to each photodiode is equal to the value obtained by dividing the voltage applied to the both ends of the serial circuit by the number of photodiodes. Therefore, the range of permissible fluctuation in the voltage during the voltage control is increased by the number of photodiodes, and the voltage control becomes easier.

Here, a plurality of photodiodes connected in series according to a conventional technique are described with reference to the attached drawing. FIG. 5 is a cross-sectional view showing conventional photodiodes provided on a liquid crystal display panel. In FIG. 5, only conductors and semiconductors are hatched.

As shown in FIG. 5, PIN diodes 101-103 are provided on a glass substrate 100 as a base for the active matrix substrate. The PIN diodes 101-103 include respectively silicon layers 104-106.

In the silicon layer 104 composing the PIN diode 101, a p-layer, an i-layer and an n-layer are formed along the planar direction. Similarly, p-layers, i-layers and n-layers are formed in the silicon layer 105 composing the PIN diode 102 and the silicon layer 106 composing the PIN diode 103.

The n-layer of the PIN diode 101 and the p-layer of the PIN diode 102 are connected electrically to each other via a metal wiring 110, and the n-layer of the PIN diode 102 and the p-layer of the PIN diode 103 are connected via a metal wiring 111. These three PIN diodes 101-103 are connected in series to configure one photo sensor.

Further, a metal wiring 109 is connected to the player of the PIN diode 101 positioned at one end, and a metal wiring 112 is connected to the n-layer of the PIN diode 103 positioned at the other end. A bias voltage Vb is applied between the metal wiring 112 and the metal wiring 109 in a direction reverse to the forward direction of the PIN diodes 101-103.

Here, when the voltage at each diode is vb, Vb=3×vb. When the permissible fluctuation range for the voltage vb at each PIN diode is Δvb, the permissible fluctuation range for the bias voltage Vb will be 333 Δvb.

In this manner, by connecting a plurality of PIN diodes in series, the permissible fluctuation range is increased and the voltage control become easy, and thus noise occurrence caused by the dark current can be suppressed. In FIG. 5, numeral 114 and 113 denotes interlayer insulation films. Numeral 115 denotes a liquid crystal layer. Numeral 116 denotes a counter substrate, only the appearance is shown.

### DISCLOSURE OF INVENTION

### Problem to be Solved by the Invention

Recently, for display devices such as a liquid crystal display device, decreasing the regions surrounding the display region is required, and accordingly, spaces for arranging photo sensors is decreased. Therefore, it is required to downsize the photo sensor as shown in FIG. 5 while suppressing occurrence of noise caused by the dark current.

However, as shown in FIG. 5, since formation of metal wirings is necessary for connecting a plurality of photodiodes in series, there is a limit in downsizing the thus configured photo sensor.

An object of the present invention is to provide a photo sensor that can solve the above-described problems and that can be downsized while occurrence of noise due to dark current is suppressed, and a display device including the photo sensor.

### Means for Solving Problem

For achieving the above-described object, a first photo sensor of the present invention is characterized in that it includes a plurality of photodiodes formed in a same silicon layer, wherein each of the plurality of the photodiodes has a p-type semiconductor region and an n-type semiconductor region formed in the silicon layer, and the plurality of the photodiodes are arranged in series so that the forward directions are aligned with each other; and, in two of the photodiodes adjacent to each other, the n-type semiconductor region of one photodiode and the p-type semiconductor region of the other photodiode are formed so that outer edges of the semiconductor regions coincide with each other or that the semiconductor regions overlap each other in the thickness direction of the silicon layer.

Further, for achieving the above-described object, a second photo sensor of the present invention is characterized in that it includes a plurality of photodiodes formed in a same silicon layer, wherein each of the plurality of the photodiodes has a p-type semiconductor region and an n-type semiconductor region formed in the silicon layer, and the plurality of the photodiodes are arranged in series so that the forward directions are aligned with each other; a region for electrically connecting the adjacent two photodiodes is provided between the adjacent two photodiodes in the silicon layer; and the region is formed to have a p-type impurity concentration equivalent to the impurity concentration in the p-type semiconductor region and an n-type impurity concentration equivalent to the impurity concentration in the n-type semiconductor region.

For achieving the above-described object, a first display device of the present invention is characterized in that it has an active matrix substrate on which a plurality of active elements are formed; and a photo sensor that outputs a signal by reaction with ambient light, wherein the photo sensor includes a plurality of photodiodes formed in a same silicon layer; the silicon layer is provided on the active matrix substrate; each of the plurality of the photodiodes has a p-type semiconductor region and an n-type semiconductor region formed in the silicon layer, and the plurality of the photodiodes are arranged in series so that the forward directions are aligned with each other; and in two of the photodiodes adjacent to each other, the n-type semiconductor region of one photodiode and the p-type semiconductor region of the other photodiode are formed so that outer edges of the semiconductor regions coincide with each other or that the semiconductor regions overlap each other in the thickness direction of the silicon layer.

Further, for achieving the above described object, a second display device of the present invention is characterized in that it has an active matrix substrate on which a plurality of active elements are formed; and a photo sensor that outputs a signal by reaction with ambient light, wherein the photo sensor includes a plurality of photodiodes formed in a same silicon layer; the silicon layer is provided on the active matrix substrate; each of the plurality of the photodiodes has a p-type semiconductor region and an n-type semiconductor region formed in the silicon layer, and the plurality of the photodiodes are arranged in series so that the forward directions are aligned with each other; a region for electrically connecting the adjacent two photodiodes is provided between the adjacent two photodiodes in the silicon layer; and the region is formed to have a p-type impurity concentration equivalent to the impurity concentration in the p-type semiconductor region and an n-type impurity concentration equivalent to the impurity concentration in the n-type semiconductor region.

### Effects of the Invention

Due to the above-described features, according to the present invention, adjacent two photodiodes among the plurality of the photodiodes arranged in series are connected electrically via a semiconductor region. Namely, the plurality of the photodiodes are connected in series without using metal wirings. Therefore, according to the present invention, a photo sensor can be downsized while suppressing occurrence of noise caused by a dark current.

### BRIEF DESCRIPTION OF DRAWINGS

FIG. 1 is a perspective view showing a display device according to an embodiment of the present invention.

FIG. 2 is a cross-sectional view showing a photo sensor according to the embodiment of the present invention.

FIG. 3 is a plan view showing the photo sensor as shown in FIG. 2.

FIG. 4 includes cross-sectional views showing a process of manufacturing the photo sensor as shown in FIGS. 2 and 3. FIGS. 4A to 4D show a series of main steps of a manufacturing process.

FIG. 5 is s cross-sectional view showing conventional photodiodes arranged on a liquid crystal display panel.

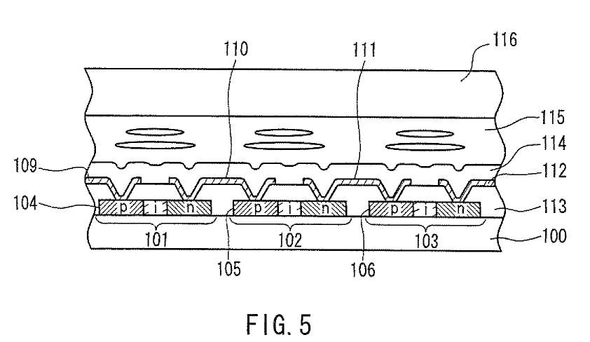

### DESCRIPTION OF THE INVENTION

A first photo sensor of the present invention is characterized in that it includes a plurality of photodiodes formed in a same silicon layer, wherein each of the plurality of the photodiodes has a p-type semiconductor region and an n-type semiconductor region formed in the silicon layer, and the plurality of the photodiodes are arranged in series so that the forward directions are aligned with each other; and, in two of the photodiodes adjacent to each other, the n-type semiconductor region of one photodiode and the p-type semiconductor region of the other photodiode are formed so that outer edges of the semiconductor regions coincide with each other or that the semiconductor regions overlap each other in the thickness direction of the silicon layer.

A second photo sensor of the present invention is characterized in that it includes a plurality of photodiodes formed in a same silicon layer, wherein each of the plurality of the photodiodes has a p-type semiconductor region and an n-type semiconductor region formed in the silicon layer, and the plurality of the photodiodes are arranged in series so that the forward directions are aligned with each other; a region for electrically connecting the adjacent two photodiodes is provided between the adjacent two photodiodes in the silicon layer; and the region is formed to have a p-type impurity concentration equivalent to the impurity concentration in the p-type semiconductor region and an n-type impurity concentration equivalent to the impurity concentration in the n-type semiconductor region.

A first display device of the present invention is characterized in that it has an active matrix substrate on which a plurality of active elements are formed; and a photo sensor that outputs a signal by reaction with ambient light, wherein the photo sensor includes a plurality of photodiodes formed in a same silicon layer; the silicon layer is provided on the active matrix substrate; each of the plurality of the photodiodes has a p-type semiconductor region and an n-type semiconductor region formed in the silicon layer, and the plurality of the photodiodes are arranged in series so that the forward directions are aligned with each other; and in two of the photodiodes adjacent to each other, the n-type semiconductor region of one photodiode and the p-type semiconductor region of the other photodiode are formed so that outer edges of the semiconductor regions coincide with each other or that the semiconductor regions overlap each other in the thickness direction of the silicon layer.

A second display device of the present invention is characterized in that it has an active matrix substrate on which a plurality of active elements are formed; and a photo sensor that outputs a signal by reaction with ambient light, wherein the photo sensor includes a plurality of photodiodes formed in a same silicon layer; the silicon layer is provided on the active matrix substrate; each of the plurality of the photodiodes has a p-type semiconductor region and an n-type semiconductor region formed in the silicon layer, and the plurality of the photodiodes are arranged in series so that the forward directions are aligned with each other; a region for electrically connecting the adjacent two photodiodes is provided between the adjacent two photodiodes in the silicon layer; and the region is formed to have a p-type impurity concentration equivalent to the impurity concentration in the p-type semiconductor region and an n-type impurity concentration equivalent to the impurity concentration in the n-type semiconductor region.

The first and second photo sensors and the first and second display devices can be configured so that each of the plurality of the photodiodes has an intrinsic semiconductor region between the p-type semiconductor region and the n-type semiconductor region.

In the present invention, the “intrinsic semiconductor region” is not limited particularly as long as it is electrically neutral in comparison with the adjacent p-type semiconductor region and the n-type semiconductor region. It should be noted that preferably the “intrinsic semiconductor region” is completely free of an impurity and/or it is a region where the conduction electron density and the hole density are equal to each other. The display device of the present invention is not limited particularly as long as it includes an active matrix substrate. It is not limited to a liquid crystal display device but it can be an EL display device.

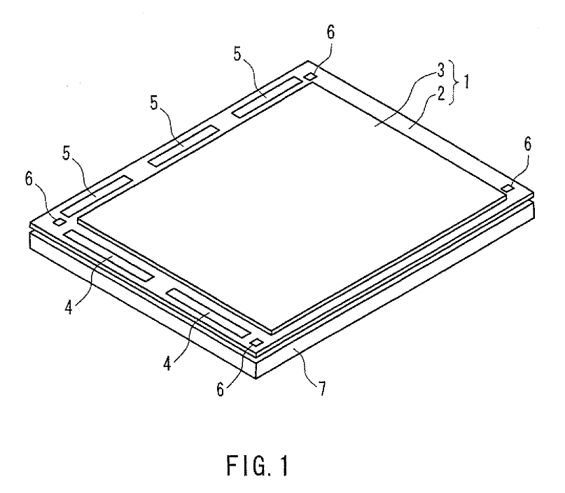

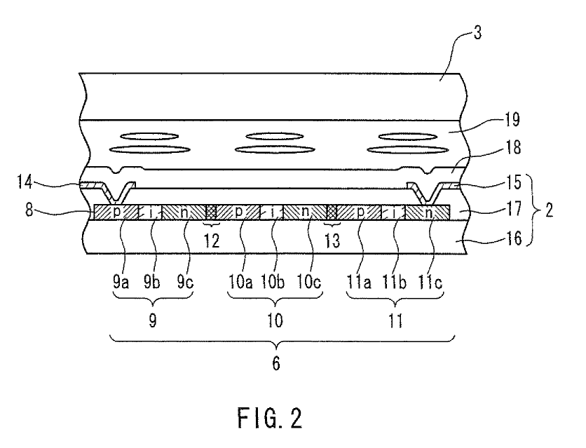

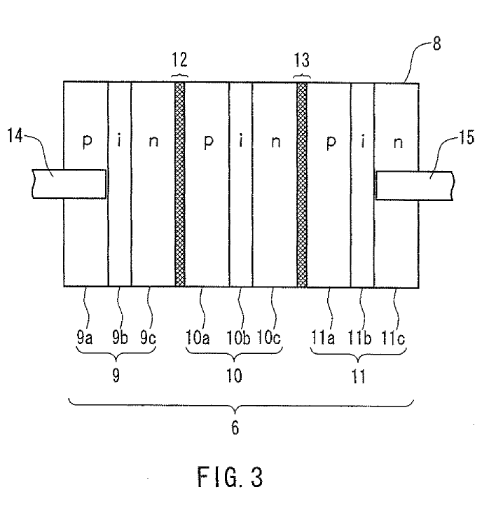

Hereinafter, the photo sensor and the display device in an embodiment of the present invention will be described more specifically below with reference to FIGS. 1 to 3. FIG. 1 is a perspective view showing a display device according to the embodiment of the present invention. FIG. 2 is a cross-sectional view showing the display device according to the embodiment of the present invention. FIG. 3 is a plan view showing the photo sensor shown in FIG. 2.

As shown in FIG. 1, the display device according to the embodiment is a liquid crystal display device provided with a liquid crystal display panel 1 and a backlight element 7 for illuminating the liquid crystal display panel 1. The display device has also a photo sensor 6 that outputs a signal by reaction with external light. The liquid crystal display panel 1 includes an active matrix substrate 2, a counter substrate 3, and a liquid crystal layer (not shown) interposed between these two substrates.

The active matrix substrate 2 includes a glass substrate (see FIG. 2) on which a plurality of pixels (not shown) are formed in matrix. Each of the pixels is mainly formed of a thin film transistor (TFT) to be an active element, and a pixel electrode formed with a transparent conductive film. A region where a plurality of pixels are arranged in matrix serves as a display region.

The counter substrate 3 is disposed so as to be superimposed on the display region of the active matrix substrate 2. The counter substrate 3 includes a counter electrode (not shown) and color filters (not shown). The color filters include, for example, coloring layers of red (R), green (G), and blue (B). The coloring layers correspond to the respective pixels.

The active matrix substrate 2 has a gate driver 4 and a data driver 5 in a region thereof surrounding the display region. Each active element is connected with the gate driver 4 via a gate line (not shown) extending in a horizontal direction, and is connected with the data driver 5 via a data line (not shown) extending in a vertical direction.

Further, in the present embodiment, the photodiode 6 also is disposed in the region surrounding the display region of the active matrix substrate 2. As shown in FIG. 2, the photo sensor 6 is formed monolithically on the active matrix substrate 2.

Specifically, the photo sensor 6 is formed of a silicon layer 8 provided on a glass substrate 16 composing the active matrix substrate 2. The silicon layer 8 is formed in the same process for forming the silicon layer composing a thin film transistor.

Further, as shown in FIGS. 2 and 3, the photo sensor 6 includes a plurality of photodiodes 9-11. The photodiodes 9-11 are formed in the same silicon layer 8. The photodiode 9 has a p-type semiconductor region (p-layer) 9a and an n-type semiconductor region (n-layer) 9c both of which are formed in the silicon layer 8. Similarly, the photodiode 10 has a p-layer 10a and an n-layer 10c both of which are formed in the silicon layer 8, and the photodiode 11 has a p-layer 11a and an n-layer 11c both of which are formed in the silicon layer 8. In the present embodiment, the photodiodes 9-11 are PIN diodes, and intrinsic semiconductor regions (i-layers) 9b, 10b and 11b are formed between the respective p-layers and n-layers.

The photodiodes 9-11 are arranged in series so that the respective forward directions are aligned with each other. Further, in the adjacent two photodiodes, the n-layer of one photodiode and the p-layer of the other photodiode overlap each other in the thickness direction of the silicon layer 8. Specifically, a part of the n-layer 9c of the photodiode 9 and a part of the p-layer 10a of the photodiode 10 overlap each other. Similarly, a part of the n-layer 10c of the photodiode 10 and a part of the p-layer 11a of the photodiode 11 overlap each other.

As a result, regions (12, 13) exist in the spacing between respective pairs of photodiodes. In these regions, the impurity concentration of the p-type impurity is equivalent to that of the p-layer of one photodiode, and the impurity concentration of the n-type impurity is equivalent to that of the n-layer of the other photodiode. At this time, impurities of both the p-type and n-type are present in the regions 12 and 13, and thus the regions 12 and 13 serve as diffused resistors but connect electrically the p-layers and the n-layers. Therefore, the photodiodes 9 and 10, the photodiodes 10 and 11 are connected electrically to each other, and the photodiodes 9-11 are connected in series.

As described above, according to the present embodiment, the photodiodes 9-11 are connected electrically in series without using metal wirings of a conventional technique. Therefore, in the photo sensor 6 of the present embodiment, it is possible to downsize of the photo sensor while suppressing occurrence of noise caused by a dark current.

In FIGS. 2 and 3, numeral 14 denotes a metal wiring connected to the p-layer 9a of the photodiode 9 positioned at one end and 15 denotes a metal wiring connected to the n-layer 11c of the photodiode 11 positioned at the other end. A reverse bias voltage is applied to the photodiodes 9-11 via the metal wirings 14 and 15. In FIG. 2, numerals 17 and 18 denote interlayer insulation films, and 19 denotes a liquid crystal layer. In FIG. 2, only the external appearance is shown for the counter substrate 3.

In the examples as shown in FIGS. 2 and 3, in two adjacent photodiodes, the n-layer of one photodiode and the p-layer of the other photodiode overlap each other in the thickness direction of the silicon layer 8, but the present embodiment is not limited to this example. Alternatively, according to the present embodiment, it is possible to form the n-layer of one of two adjacent photodiodes and the p-layer of the other of two adjacent photodiodes so that the outer edges thereof coincide with each other (without presence of the regions 12 and 13).

In this case, in the silicon layer 8, a so-called pn junction is formed between the n-layer of one photodiode and the p-layer of the other photodiode. Since an i-layer like in a pin junction does not exist in a pn junction formed in a silicon thin film, the region of depletion layer is extremely small, and the change in the bandgap in the vicinity of the grain boundary becomes steep. Thereby, a trap center (capture center) is present in the vicinity of the grain boundary, and thus a trap level is formed. As a result, due to the surface current flowing on the surface of the silicon layer 8 and the presence of the grain boundary in the silicon layer 8, a carrier capture is performed freely and the dark current is increased considerably in this pn junction. Namely, the pn junction formed on the silicon thin film is equalized substantially to a state of an ohmic contact.

Similarly therefore, in a case where the outer edges of the n-layer of a photodiode and the p-layer of the other photodiode coincide with each other, the photodiode 9 is connected electrically to the photodiode 10 and the photodiode 10 is connected electrically to the photodiode 11, and the photodiode 9-11 are connected in series. In the present embodiment, a case where the outer edge of the n-layer of one of the two adjacent photodiodes and the p-layer of the other of the two adjacent photodiodes denotes a case where the above-described ohmic contact is formed due to the pn junction between the n-layer of one photodiode and the p-layer of the other photodiode. When the lengths of the regions 12 and 13 in the forward direction of the photodiodes are extremely short, it can be considered as the pn junction is formed as in the case of coincidence. Similarly in this case, the state is equalized to the state of the ohmic contact.

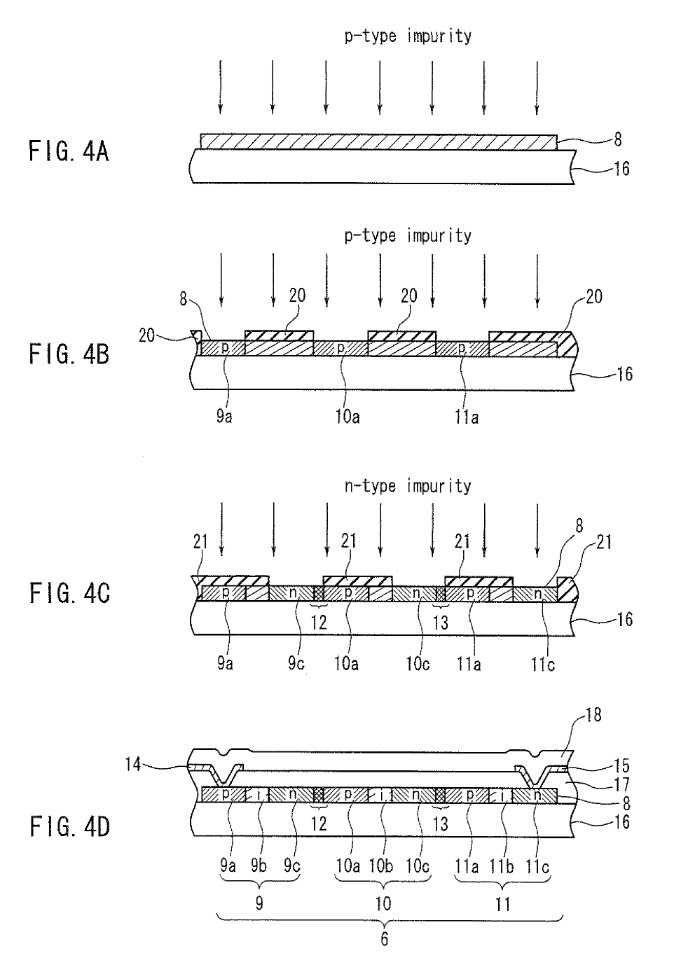

Next, the process for manufacturing a photo sensor in the present embodiment will be described with reference to FIG. 4. FIG. 4 includes cross-sectional views showing the process of manufacturing the photo sensor as shown in FIGS. 2 and 3, and FIGS. 4A to 4D show a series of main steps of the manufacturing process.

As shown in FIG. 4A, first, a silicon thin film is formed on one surface of a glass substrate 16 as a base by a CVD (Chemical Vapor Deposition) method or the like. Then, the silicon thin film is patterned by photolithography so as to form the silicon layer 8 to be a photo sensor 6. In the present embodiment, it is also possible to form, under the silicon layer 8, a metal film serving as a light-shielding film or an insulation film for insulating the metal film and the silicon layer 8.

In the present embodiment, the silicon thin film serving as the silicon layer 8 can be formed of any of an amorphous silicon layer, a polysilicon layer or a continuous grain silicon (CGS) film. It is preferably formed of a CGS film due to its high electron mobility.

The CGS film can be formed in the following manner for example. First, a silicon oxide film and an amorphous silicon layer are formed in this order on the glass substrate 16. Next, a nickel thin film serving as a catalyst for accelerating crystallization is formed on the surface layer of the amorphous silicon layer. Next, the nickel thin film and the amorphous silicon layer are reacted with each other by heating so that a crystal silicon layer is formed on the interface. Later, an unreacted nickel film and a nickel silicide layer are removed by etching or the like. Next, the remaining silicon layer is annealed to promote crystallization, thereby the CGS film is obtained.

A process for forming TFT is applied to the process for forming the silicon layer 8. Since the silicon layer 8 is n-type, subsequently the dose of an impurity in the silicon layer 8 is adjusted for forming an i-layer. Specifically, an ion doping is carried out by using a p-type impurity such as boron (B) and indium (In).

Next, as shown in FIG. 4B, ions of the p-type impurity are implanted in the silicon layer 8, thereby forming the p-layers 9a, 10a and 11a. Specifically, a resist pattern 20 with apertures of regions for forming the p-layers 9a, 10a and 11a, is formed. Subsequently, boron (B), indium (In) and the like are implanted in the silicon layer 8 by ion doping using the resist pattern 20 as a mask. Later, the resist pattern 20 is removed.

Next, as shown in FIG. 4C, ions of an n-type impurity are implanted in the silicon layer 8, thereby forming n-layers 9c, 10c, 11c and the regions 12 and 13. In the present embodiment, this step is carried out by using the step for forming the source region and the drain region of the TFT that composes the active elements to drive the pixels.

Specifically, a resist pattern 21 with apertures for regions for forming the n-layers 9c, 10c and 11c, is formed. At this time, the aperture of the resist pattern 21 is formed to expose partially the p-layers 10a and 11a. Then, phosphorus (P), arsenic (As) and the like are implanted in the silicon layer 8 by ion doping using the resist pattern 21 as a mask.

As a result, the n-layers 9c and 10c are formed to overlap partially with the p-layers 10a and 11a. The regions 12 and 13 formed due to the overlap of the p-layers and the n-layers make the regions to connect electrically photodiodes adjacent to each other, as described above. Later, the resist pattern 21 is removed.

In the step as shown in FIG. 4C, the resist pattern 21 can be formed so that the periphery of the aperture and the outer edges of the players 10a and 11a coincide with each other. In this case, the regions 12 and 13 are not formed. The outer edge of the n-layer 9c coincides with the outer edge of the p-layer 10a, and the outer edge of the n-layer 10c coincides with the outer edge of the p-layer 11a, and thus these n-layers and the p-layers are pn-joined. Alternatively, the periphery of the aperture of the resist pattern 21 and the outer edges of the players 10a and 11a can coincide with each other due to the error at the time of forming the resist pattern 21.

Subsequently, a silicon nitride film or a silicon oxide film is formed by a CVD method so as to form the interlayer insulation film 17. Then, open holes are formed at positions of the interlayer insulation film 17 so as to correspond to the p-layer 9a and the n-layer 11c, and the metal wirings 14 and 15 are formed. Later, the CVD is carried out further to form the interlayer insulation film 18.

By performing the steps as shown in FIGS. 4A to 4D in this manner, the photo sensor 6 of the present embodiment as shown in FIGS. 2 and 3 is formed. In the example as shown in FIGS. 2-4, the photo sensor 6 is composed of three photodiodes 9-11, but the configuration is not limited to this example. The number of the photodiodes of the photo sensor 6 can be determined suitably.

Similarly, the steps of forming the regions 12 and 13 are not limited to the example as shown in FIG. 4. The regions 12 and 13 can be formed for instance by forming a p-layer of a photodiode and a n-layer of an adjacent photodiode with a certain spacing, and by implanting a p-type impurity and an n-type impurity in the region therebetween by a separate ion doping step.

### INDUSTRIAL APPLICABILITY

The photo sensor of the present invention can be mounted on a display device such as a liquid crystal display device or an EL display device, without being limited to these examples. Therefore, the photo sensor of the present invention and furthermore a display device equipped with the same provide industrial applicability.

1. A photo sensor comprising a plurality of photodiodes formed in a same silicon layer, wherein
each of the plurality of the photodiodes has a p-type semiconductor region and an n-type semiconductor region formed in the silicon layer, and the plurality of the photodiodes are arranged in series so that the forward directions are aligned with each other; and
in two of the photodiodes adjacent to each other, the n-type semiconductor region of one photodiode and the p-type semiconductor region of the other photodiode are formed so that outer edges of the semiconductor regions coincide with each other or that the semiconductor regions overlap each other in the thickness direction of the silicon layer.

2. The photo sensor according to claim 1, wherein each of the plurality of the photodiodes has an intrinsic semiconductor region between the p-type semiconductor region and the n-type semiconductor region.

3. A display device comprising: an active matrix substrate on which a plurality of active elements are formed; and a photo sensor that outputs a signal by reaction with ambient light, wherein
the photo sensor comprises a plurality of photodiodes formed in a same silicon layer;
the silicon layer is provided on the active matrix substrate;
each of the plurality of the photodiodes has a p-type semiconductor region and an n-type semiconductor region formed in the silicon layer, and the plurality of the photodiodes are arranged in series so that the forward directions are aligned with each other; and
in two of the photodiodes adjacent to each other, the n-type semiconductor region of one photodiode and the p-type semiconductor region of the other photodiode are formed so that outer edges of the semiconductor regions coincide with each other or that the semiconductor regions overlap each other in the thickness direction of the silicon layer.

4. The display device according to claim 3, wherein each of the plurality of the photodiodes has an intrinsic semiconductor region between the p-type semiconductor region and the n-type semiconductor region.

5. A photo sensor comprising a plurality of photodiodes formed in a same silicon layer, wherein
each of the plurality of the photodiodes has a p-type semiconductor region and an n-type semiconductor region formed in the silicon layer, and the plurality of the photodiodes are arranged in series so that the forward directions are aligned with each other;
a region for electrically connecting the adjacent two photodiodes is provided between the adjacent two photodiodes in the silicon layer; and
the region is formed to have a p-type impurity concentration equivalent to the impurity concentration in the p-type semiconductor region and an n-type impurity concentration equivalent to the impurity concentration in the n-type semiconductor region.

6. A display device comprising: an active matrix substrate on which a plurality of active elements are formed; and a photo sensor that outputs a signal by reaction with ambient light, wherein
the photo sensor comprises a plurality of photodiodes formed in a same silicon layer;
the silicon layer is provided on the active matrix substrate;
each of the plurality of the photodiodes has a p-type semiconductor region and an n-type semiconductor region formed in the silicon layer, and the plurality of the photodiodes are arranged in series so that the forward directions are aligned with each other;
a region for electrically connecting the adjacent two photodiodes is provided between the adjacent two photodiodes in the silicon layer; and
the region is formed to have a p-type impurity concentration equivalent to the impurity concentration in the p-type semiconductor region and an n-type impurity concentration equivalent to the impurity concentration in the n-type semiconductor region.
